(19) United States
(12) Patent Application Publication
(10) Pub. No.: US 2026/0100216 A1
(43) Pub. Date: Apr. 9, 2026

(54) DYNAMIC RANDOM-ACCESS MEMORY (DRAM) DEVICE

(71) Applicant: NANYA TECHNOLOGY CORPORATION, New Taipei City (TW)

(72) Inventor: Chih-Jen Chen, New Taipei City (TW)

(73) Assignee: NANYA TECHNOLOGY CORPORATION, New Taipei City (TW)

(21) Appl. No.: 18/909,931

(22) Filed: Oct. 8, 2024

(51) Int. Cl. G11C 11/4074; G11C 11/4099

(52) U.S. Cl. CPC G11C 11/4074; G11C 11/4099

(57) ABSTRACT

A dynamic random-access memory (DRAM) device is provided. The DRAM device includes a slave DRAM chip and a master DRAM chip. The slave DRAM chip includes a slave control circuit and a slave power circuit. The slave control circuit generates a slave control signal according to a slave category signal and a setting signal. The slave power circuit stops generating at least one of slave voltages in response to a first value of the slave control signal and generates the slave voltages in response to a second value of the slave control signal. The master DRAM chip includes a master control circuit. The master control circuit generates a master control signal according to a master category signal and the setting signal, and controls the master DRAM chip to generate master voltages according to the master control signal. The slave category signal is different from the master category signal.

### BACKGROUND

### Technical Field

The disclosure relates to a memory device, and in particular to a dynamic random-access memory (DRAM) device.

### Description of Related Art

Dynamic random-access memory (DRAM) devices include first category DRAM chips and second category DRAM chips. Dynamic random-access memory can be sold in different product categories. For example, a first product category DRAM device may use a first category DRAM chip and a second category DRAM chip. Only the first category DRAM chip is used in the second product category DRAM device.

It should be noted that the second category DRAM chip still generates power in both the first product category DRAM device and the second product category DRAM device. In other words, the power consumption of the second product category DRAM device is not reduced without using the second category DRAM chip.

### SUMMARY

The disclosure provides a dynamic random-access memory (DRAM) device which can reduce power consumption according to the product category of the DRAM device.

In an embodiment of the disclosure, a DRAM device includes at least one slave DRAM chip and a master DRAM chip. Each of the at least one slave DRAM chip includes a slave control circuit and a slave power circuit. The slave control circuit generates a slave control signal according to a slave category signal and a setting signal. The slave power circuit is coupled to the slave control circuit. The slave power circuit stops generating at least one of multiple slave voltages in response to a first value of the slave control signal and generates the slave voltages in response to a second value of the slave control signal. The master DRAM chip is coupled to the at least one slave DRAM chip. The master DRAM chip controls an operation of the at least one slave DRAM chip. The master DRAM chip includes a master control circuit. The master control circuit generates a master control signal according to the master category signal and the setting signal, and controls the master DRAM chip to generate multiple master voltages according to the master control signal. The slave category signal is different from the master category signal.

Based on the above, the slave power circuit of the slave DRAM chip stops generating at least one of the slave voltages in response to the first value of the slave control signal. Therefore, when the DRAM device only uses the first category DRAM chip, the slave power circuit of the slave DRAM chip can be controlled to stop generating at least one of the slave voltages. In this way, when the DRAM device only uses first category DRAM chip, the power consumption of the DRAM device can be reduced.

### BRIEF DESCRIPTION OF THE DRAWINGS

FIG. 1 is a schematic diagram of a dynamic random-access memory (DRAM) device according to an embodiment of the disclosure.

FIG. 2 is a schematic diagram of a DRAM device according to an embodiment of the disclosure.

FIG. 3 is a schematic diagram of a slave control circuit according to an embodiment of the disclosure.

FIG. 4 is a schematic diagram of a master control circuit according to an embodiment of the disclosure.

FIG. 5 is a schematic diagram of a DRAM device according to an embodiment of the disclosure.

FIG. 6 is a schematic diagram of a DRAM device according to an embodiment of the disclosure.

FIG. 7 is a schematic diagram of a DRAM device according to an embodiment of the disclosure.

FIG. 8 is a schematic diagram of a slave power circuit according to an embodiment of the disclosure.

FIG. 9 is a schematic diagram of a master power circuit according to an embodiment of the disclosure.

### DESCRIPTION OF THE EMBODIMENTS

A disclosure may be understood by reference to the following detailed description, taken in conjunction with the drawings as described below. It is noted that, for purposes of illustrative clarity and being easily understood by the readers, various drawings of the disclosure show a portion of an electronic device, and certain elements in various drawings may not be drawn to scale. In addition, the number and dimension of each device shown in drawings are only illustrative and are not intended to limit the scope of the disclosure.

Certain terms are used throughout the description and following claims to refer to particular components. As one skilled in the art will understand, electronic equipment manufacturers may refer to a component by different names. This document does not intend to distinguish between components that differ in name but not function. In the following description and in the claims, the terms “include”, “comprise”, and “have” are used in an open-ended fashion, and thus should be interpreted to mean “include, but not limited to . . . ”. Thus, when the terms “include”, “comprise”, and/or “have” are used in the description of the disclosure, the corresponding features, areas, steps, operations, and/or components would be pointed to existence, but not limited to the existence of one or a plurality of the corresponding features, areas, steps, operations, and/or components.

It will be understood that when an element is referred to as being “coupled to”, “connected to”, or “conducted to” another element, it may be directly connected to the other element and established directly electrical connection, or intervening elements may be presented therebetween for relaying electrical connection (indirectly electrical connection). In contrast, when an element is referred to as being “directly coupled to”, “directly conducted to”, or “directly connected to” another element, there are no intervening elements presented.

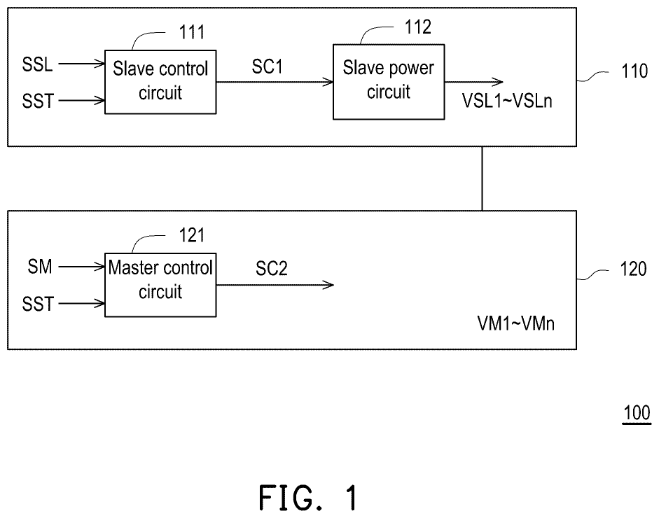

Please refer to FIG. 1, which is a schematic diagram of a dynamic random-access memory (DRAM) device according to an embodiment of the disclosure. In this embodiment, a DRAM device 100 includes a slave DRAM chip 110 and a master DRAM chip 120. The slave DRAM chip 110 includes a slave control circuit 111 and a slave power circuit 112. The slave control circuit 111 generates a slave control signal SC1 according to a slave category signal SSL and a setting signal SST. The slave power circuit 112 is coupled to the slave control circuit 111. The slave power circuit 112 stops generating at least one of slave voltages VSL1 to VSLn according to the slave control signal SC1.

In this embodiment, the slave power circuit 112 stops generating at least one of the slave voltages VSL1 to VSLn in response to a first value of the slave control signal SC1. The slave power circuit 112 generates the slave voltages VSL1 to VSLn in response to a second value of the slave control signal SC1. For example, the first value of the slave control signal SC1 may be a first voltage value, a first current value, a first logical value or a first duty cycle. The second value of the slave control signal SC1 may be a second voltage value, a second current value, a second logical value or a second duty cycle. The second value is different from the first value.

In this embodiment, the master DRAM chip 120 is coupled to the slave DRAM chip 110. The master DRAM chip 120 controls the operation of the slave DRAM chip 110. The master DRAM chip 120 includes a master control circuit 121. The master control circuit 121 generates a master control signal SC2 according to a master category signal SM and the setting signal SST, and controls the master DRAM chip 120 to generate master voltages VM1 to VMn according to the master control signal SC2.

In this embodiment, the slave category signal SSL is a category mark of the slave DRAM chip 110. The master category signal SM is a category mark of the master DRAM chip 120. Therefore, the slave category signal SSL is different from the master category signal SM. For example, the slave category signal SSL has a first value. The master category signal SM has a second value.

It is worth mentioning here that the slave power circuit 112 of the slave DRAM chip 110 stops generating at least one of the slave voltages VSL1 to VSLn in response to the first value of the slave control signal SC1. Therefore, when the DRAM device only uses the master DRAM chip 120, the slave power circuit 112 of the slave DRAM chip 110 may be controlled to stop generating at least one of the slave voltages VSL1 to VSLn. In this way, when the DRAM device 100 only uses the master DRAM chip 120, the power consumption of the DRAM device 100 can be reduced.

For example, the DRAM device 100 of the first product category uses the slave DRAM chip 110 and the master DRAM chip 120. Therefore, the slave DRAM chip 110 generates the slave voltages VSL1 to VSLn. The master DRAM chip 120 generates the master voltages VM1 to VMn. For example, the DRAM device 100 of the second product category only uses the master DRAM chip 120. Therefore, the master DRAM chip 120 generates the master voltages VM1 to VMn. The slave DRAM chip 110 does not generate the slave voltages VSL1 to VSLn. Therefore, the power consumption of the DRAM device 100 of the second product category is lower than the power consumption of the DRAM device 100 of the first product category.

In this embodiment, the slave DRAM chip 110 and the master DRAM chip 120 are stacked on each other. For example, the slave DRAM chip 110 and the master DRAM chip 120 are stacked to form a three-dimensional (3D) stacked DRAM structure, but the disclosure is not limited thereto.

For ease of explanation, this embodiment takes a single slave DRAM chip 110 as an example. However, the disclosure is not limited to the number of slave DRAM chips 110. In some embodiments, the number of slave DRAM chips 110 may be plural.

In this embodiment, the slave voltages VSL1 to VSLn are respectively voltage signals required for the operation of the slave DRAM chip 110. The slave voltages VSL1 to VSLn may be one of a bandgap reference voltage, a power supply voltage, and a pumping voltage respectively. The master voltages VM1 to VMn are respectively the voltage signals required for the operation of the master DRAM chip 120. Similarly, the master voltages VM1 to VMn may be one of the bandgap reference voltage, the power supply voltage, and the pumping voltage respectively.

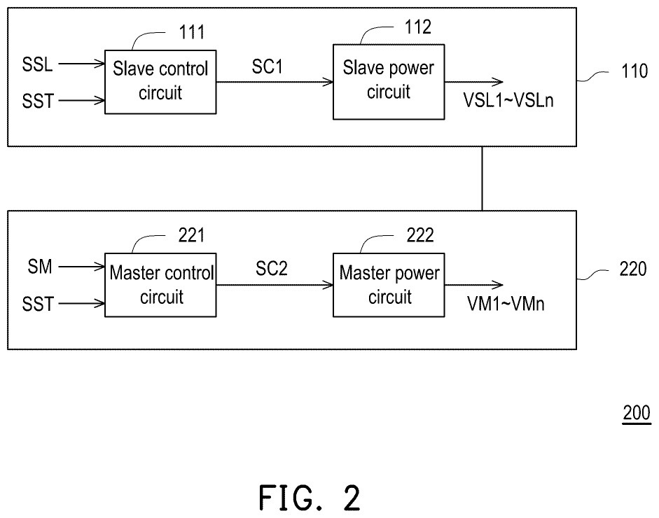

Please refer to FIG. 2, which is a schematic diagram of a DRAM device according to an embodiment of the disclosure. In this embodiment, a DRAM device 200 includes a slave DRAM chip 110 and a master DRAM chip 220. The slave DRAM chip 110 includes a slave control circuit 111 and a slave power circuit 112. The operations of the slave control circuit 111 and the slave power circuit 112 have been clearly explained in the embodiment of FIG. 1 and are not repeated here.

In this embodiment, the master DRAM chip 220 controls the operation of the slave DRAM chip 110. The master DRAM chip 220 includes a master control circuit 221 and a master power circuit 222. The master control circuit 221 generates the master control signal SC2 according to the master category signal SM and the setting signal SST. The master power circuit 222 is coupled to the master control circuit 221. The master power circuit 222 stops generating at least one of the master voltages VM1 to VMn in response to a first value of the master control signal SC2, and generates the master voltage VM1 to VMn in response to a second value of the master control signal SC2.

For example, a logical value of the slave category signal SSL is set to a first logical value (for example, a first value). A logical value of the master category signal SM is set to a second logical value (for example, a second value). When the logical value of the setting signal SST is the first logical value, a logical value of the slave control signal SC1 is the first logical value. Therefore, the slave power circuit 112 stops generating at least one of the slave voltages VSL1 to VSLn. In another aspect, when the logical value of the setting signal SST is the second logical value, the logical value of the slave control signal SC1 is the second logical value. Therefore, the slave power circuit 112 generates the slave voltages VSL1 to VSLn.

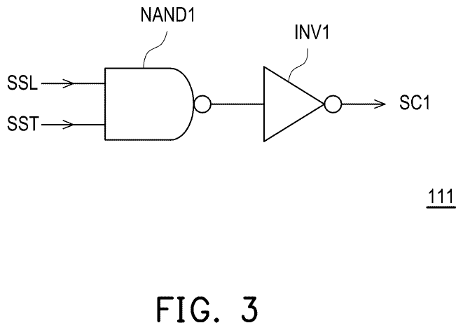

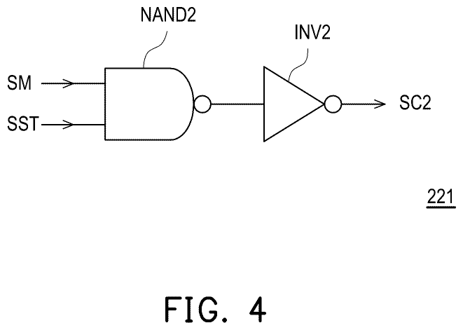

Please refer to FIG. 2, FIG. 3, and FIG. 4. FIG. 3 is a schematic diagram of a slave control circuit according to an embodiment of the disclosure. FIG. 4 is a schematic diagram of a master control circuit according to an embodiment of the disclosure. In this embodiment, the first logical value is, for example, a high logical value. The second logical value is, for example, a low logical value. The slave control circuit 111 performs a logical AND operation on the slave category signal SSL and the setting signal SST to generate the slave control signal SC1. For example, the slave control circuit 111 includes a NAND gate NAND1 and an inverter INV1. A first input terminal of the NAND gate NAND1 receives the slave category signal SSL. A second input terminal of the NAND gate NAND1 receives the setting signal SST. An input terminal of the inverter INV1 is coupled to an output terminal of the NAND gate NAND1. An output terminal of the inverter INV1 outputs the slave control signal SC1.

The master control circuit 221 performs a logical AND operation on the master category signal SM and the setting signal SST to generate the master control signal SC2. For example, the master control circuit 221 includes a NAND gate NAND2 and an inverter INV2. A first input terminal of the NAND gate NAND2 receives the master category signal SM. A second input terminal of the NAND gate NAND2 receives the setting signal SST. An input terminal of the inverter INV2 is coupled to an output terminal of the NAND gate NAND2. An output terminal of the inverter INV2 outputs the master control signal SC2.

It should be noted that the first logical value is, for example, the high logical value. The second logical value is, for example, the low logical value. Therefore, the circuit design of the slave control circuit 111 is generally similar to the circuit design of the master control circuit 221. In this way, the circuit design complexity of the slave control circuit 111 and the master control circuit 221 may be reduced.

In some embodiments, the first logical value may be a low logical value. The second logical value may be, for example, a high logical value. Therefore, the slave control circuit 111 may perform the logical NOR operation on the slave category signal SSL and the setting signal SST to generate the slave control signal SC1. The master control circuit 221 may perform a logical NOR operation on the master category signal SM and the setting signal SST to generate the master control signal SC2.

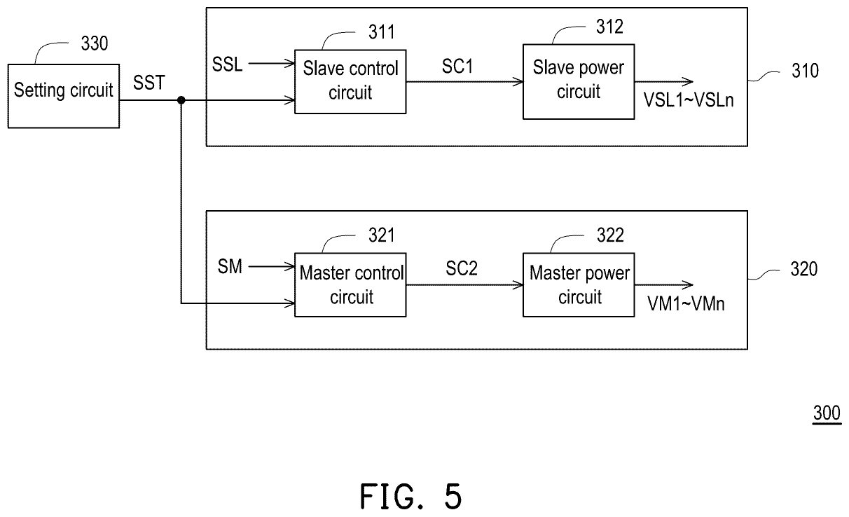

Please refer to FIG. 5, is a schematic diagram of a DRAM device according to an embodiment of the disclosure. In this embodiment, a DRAM device 300 includes a slave DRAM chip 310, a master DRAM chip 320, and a setting circuit 330. The slave DRAM chip 310 includes a slave control circuit 311 and a slave power circuit 312. The master DRAM chip 320 includes a master control circuit 321 and a master power circuit 322. The setting circuit 330 is coupled to the slave control circuit 311 and the master control circuit 321. The setting circuit 330 generates the setting signal SST according to the setting operation of the DRAM device 300.

In this embodiment, the setting circuit 330 may generate the setting signal SST according to the setting operation of the slave DRAM chip 310. The logical value of the slave category signal SSL is set to the first logical value (for example, the first value). The logical value of the master category signal SM is set to the second logical value (for example, the second value). For example, the first logical value is, for example, the high logical value. The second logical value is, for example, the low logical value. When both the slave DRAM chip 310 and the master DRAM chip 320 are used, the setting circuit 330 may generate the setting signal SST according to the setting operation of the DRAM device 300. At this time, the logical value of the setting signal SST is the second logical value. Therefore, the slave control circuit 311 performs a logical AND operation on the slave category signal SSL and the setting signal SST to generate the slave control signal SC1. At this time, the logical value of the slave control signal SC1 is the second logical value. The master control circuit 321 performs a logical AND operation on the master category signal SM and the setting signal SST to generate the master control signal SC2. At this time, a logical value of the master control signal SC2 is the second logical value. Therefore, the slave power circuit 312 generates the slave voltages VSL1 to VSLn. The master power circuit 322 generates the master voltage VM1 to VMn.

When the slave DRAM chip 310 is not in use, the setting circuit 330 may generate the setting signal SST according to the setting operation of the DRAM device 300. At this time, the logical value of the setting signal SST is the first logical value. Therefore, the logical value of the slave control signal SC1 is the first logical value. The logical value of the master control signal SC2 is the second logical value. Therefore, the slave power circuit 312 does not generate at least one of the slave voltages VSL1 to VSLn. The master power circuit 322 still generates the master voltage VM1 to VMn.

In this embodiment, the setting circuit 330 may be implemented by a fuse circuit, but the disclosure is not limited thereto.

In this embodiment, the slave control circuit 311 is implemented by, for example, the slave control circuit 111 in FIG. 3. The master control circuit 321 is implemented by, for example, the master control circuit 221 in FIG. 4.

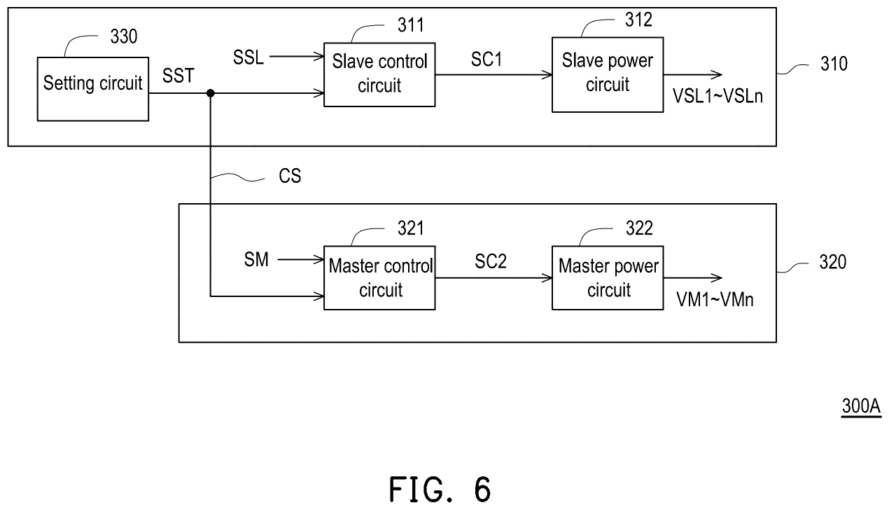

Please refer to FIG. 6, which is a schematic diagram of a DRAM device according to an embodiment of the disclosure. In this embodiment, a DRAM device 300A includes a slave DRAM chip 310, a master DRAM chip 320, and a setting circuit 330. Different from the embodiment of FIG. 5, the setting circuit 330 of this embodiment is disposed in the slave DRAM chip 310.

In this embodiment, the setting circuit 330 may provide the setting signal SST to the master control circuit 321 by a connector CS. The connector CS is, for example, an electrical connector including a through silicon via (TSV), but the disclosure is not limited thereto.

In some embodiments, the DRAM device 300A includes multiple slave DRAM chips 310. The setting circuit 330 may be disposed in one of the slave DRAM chips 310. The setting signal SST may be provided to the master control circuit 321 and the slave control circuits 311 of other slave DRAM chips 310 by the connector CS.

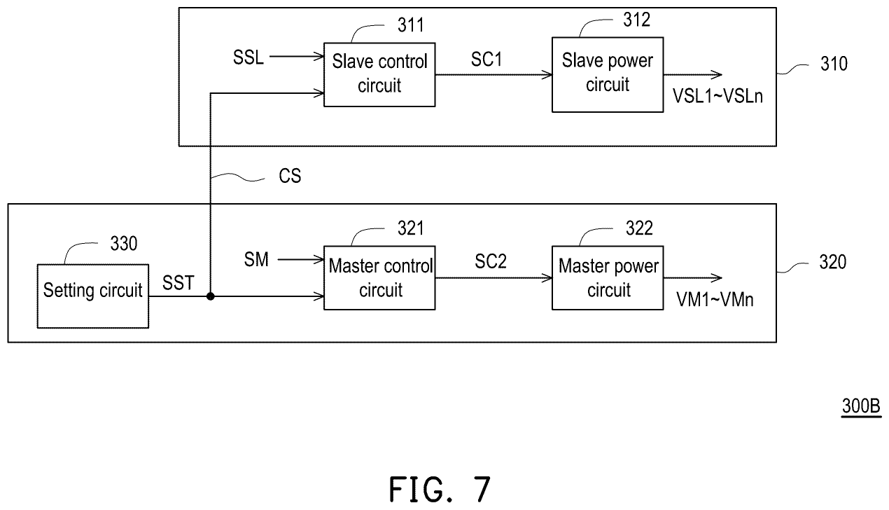

Please refer to FIG. 7, which is a schematic diagram of a DRAM device according to an embodiment of the disclosure. In this embodiment, a DRAM device 300B includes a slave DRAM chip 310, a master DRAM chip 320, and a setting circuit 330. Different from the embodiment of FIG. 5, the setting circuit 330 of this embodiment is disposed in the master DRAM chip 320. In this embodiment, the setting circuit 330 may provide the setting signal SST to the slave control circuit 311 by the connector CS.

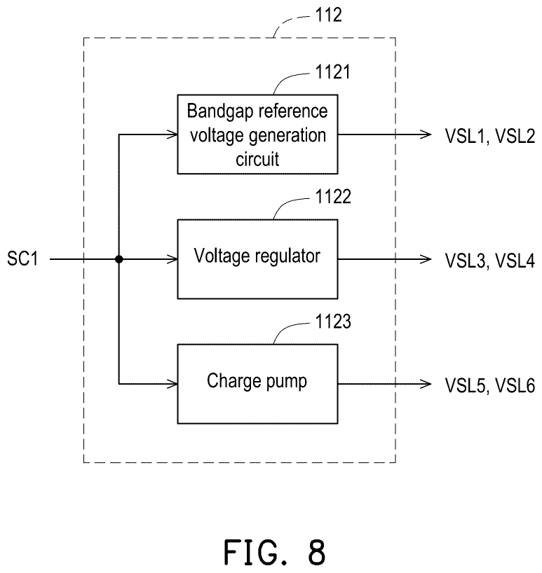

Please refer to FIG. 2 and FIG. 8. FIG. 8 is a schematic diagram of a slave power circuit according to an embodiment of the disclosure. In this embodiment, the slave power circuit 112 includes a bandgap reference voltage generation circuit 1121, a voltage regulator 1122, and a charge pump 1123. The bandgap reference voltage generation circuit 1121 is coupled to the slave control circuit 111. The bandgap reference voltage generation circuit 1121 stops generating the slave voltages VSL1 and VSL2 in response to the first value of the slave control signal SC1. The bandgap reference voltage generation circuit 1121 generates the slave voltages VSL1 and VSL2 in response to the second value of the slave control signal SC1. For example, the slave voltage VSL1 may be a bandgap reference voltage “AnlgRef” required by the slave DRAM chip 110, but the disclosure is not limited thereto. The slave voltage VSL2 may be a bandgap reference voltage “VCCARef” required by the slave DRAM chip 110, but the disclosure is not limited thereto. The bandgap reference voltage generation circuit 1121 of the disclosure may generate at least one bandgap reference voltage, and is not limited to the number of bandgap reference voltages in this embodiment.

In this embodiment, the voltage regulator 1122 is coupled to the slave control circuit 111. The voltage regulator 1122 stops generating the slave voltages VSL3 and VSL4 in response to the first value of the slave control signal SC1. The voltage regulator 1122 generates the slave voltages VSL3 and VSL4 in response to the second value of the slave control signal SC1. For example, the slave voltage VSL3 may be a power supply voltage “VCCA” required by the slave DRAM chip 110, but the disclosure is not limited thereto. The slave voltage VSL4 may be a power supply voltage “VDLL” required by the slave DRAM chip 110, but the disclosure is not limited thereto. The voltage regulator 1122 of the disclosure may generate at least one power supply voltage, and is not limited to the number of power supply voltages in this embodiment. For example, the power supply voltage “VCCA” may be a power supply voltage for a memory cell array of the slave DRAM chip 110. The power supply voltage “VDLL” may be a power supply voltage of a delay-line loop (DLL) of the slave DRAM chip 110.

In this embodiment, the charge pump 1123 is coupled to the slave control circuit 111. The charge pump 1123 stops generating the slave voltages VSL5 and VSL6 in response to the first value of the slave control signal SC1. The charge pump 1123 generates the slave voltages VSL5 and VSL6 in response to the second value of the slave control signal SC1. For example, the slave voltage VSL5 may be a pumping voltage “VCCP” required by the slave DRAM chip 110, but the disclosure is not limited thereto. The slave voltage VSL6 may be a pumping voltage “VBB” required by the slave DRAM chip 110, but the disclosure is not limited thereto. The charge pump 1123 of the disclosure may generate at least one pumping voltage, and is not limited to the number of pumping voltages in this embodiment. For example, the pumping voltage “VCCP” may be a word line voltage for the memory cell array of the slave DRAM chip 110. The pumping voltage “VBB” may be the negative bias of the slave DRAM chip 110.

In some embodiments, the slave power circuit 112 may include one of the bandgap reference voltage generation circuit 1121, the voltage regulator 1122, and the charge pump 1123. For example, the slave power circuit 112 includes the bandgap reference voltage generation circuit 1121, but the disclosure is not limited thereto. Therefore, the slave power circuit 112 stops generating the slave voltages VSL1 and VSL2 in response to the first value of the slave control signal SC1.

In some embodiments, the slave power circuit 112 may include two of the bandgap reference voltage generation circuit 1121, the voltage regulator 1122, and the charge pump 1123. For example, the slave power circuit 112 includes the bandgap reference voltage generation circuit 1121 and the charge pump 1123, but the disclosure is not limited thereto. Therefore, the slave power circuit 112 stops generating the slave voltages VSL1, VSL2, VSL5, and VSL6 in response to the first value of the slave control signal SC1.

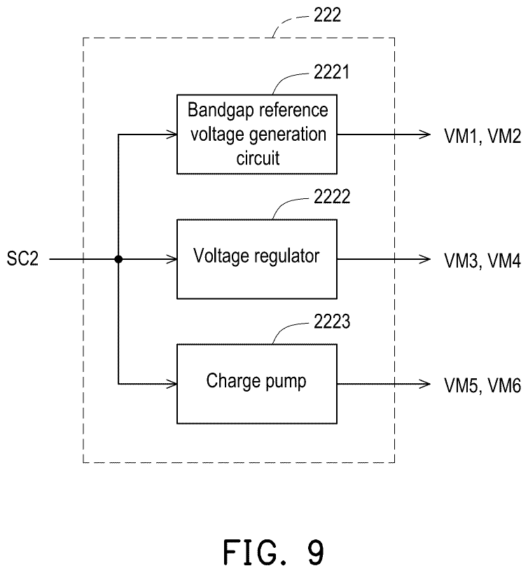

Please refer to FIG. 2 and FIG. 9. FIG. 9 is a schematic diagram of a master power circuit according to an embodiment of the disclosure. In this embodiment, a master power circuit 222 includes a bandgap reference voltage generation circuit 2221, a voltage regulator 2222, and a charge pump 2223. The bandgap reference voltage generation circuit 2221 is coupled to the master control circuit 221. The bandgap reference voltage generation circuit 2221 stops generating the master voltages VM1 and VM2 in response to the first value of the master control signal SC2. The bandgap reference voltage generation circuit 2221 generates the master voltages VM1 and VM2 in response to the second value of the master control signal SC2. For example, the master voltage VM1 may be a bandgap reference voltage “AnlgRef” required by the master DRAM chip 220, but the disclosure is not limited thereto. The master voltage VM2 may be a bandgap reference voltage “VCCARef” required by the master DRAM chip 220, but the disclosure is not limited thereto. The bandgap reference voltage generation circuit 2221 of the disclosure may generate at least one bandgap reference voltage, and is not limited to the number of bandgap reference voltages in this embodiment.

In this embodiment, the voltage regulator 2222 is coupled to the master control circuit 221. The voltage regulator 2222 stops generating the master voltages VM3 and VM4 in response to the first value of the master control signal SC2. The voltage regulator 2222 generates the master voltages VM3 and VM4 in response to the second value of master control signal SC2. For example, the master voltage VM3 may be a power supply voltage “VCCA” required by the master DRAM chip 220, but the disclosure is not limited thereto. The master voltage VM4 may be a power supply voltage “VDLL” required by the master DRAM chip 220, but the disclosure is not limited thereto. The voltage regulator 2222 of the disclosure may generate at least one power supply voltage, and is not limited to the number of power supply voltages in this embodiment. For example, the power supply voltage “VCCA” may be a power supply voltage for a memory cell array of the master DRAM chip 220. The power supply voltage “VDLL” may be a power supply voltage of a delay-line loop (DLL) of the master DRAM chip 220.

In this embodiment, the charge pump 2223 is coupled to the master control circuit 221. The charge pump 2223 stops generating the master voltages VM5 and VM6 in response to the first value of master control signal SC2. The charge pump 2223 generates the master voltages VM5 and VM6 in response to the second value of master control signal SC2. For example, the master voltage VM5 may be a pumping voltage “VCCP” required by the master DRAM chip 220, but the disclosure is not limited thereto. The master voltage VM6 may be a pumping voltage “VBB” required by the master DRAM chip 220, but the disclosure is not limited thereto. The charge pump 2223 of the disclosure may generate at least one pumping voltage, and is not limited to the number of pumping voltages in this embodiment. For example, the pumping voltage “VCCP” may be a word line voltage for the memory cell array of the master DRAM chip 220. The pumping voltage “VBB” may be the negative bias of the master DRAM chip 220.

In some embodiments, the master power circuit 222 may include one of the bandgap reference voltage generation circuit 2221, the voltage regulator 2222, and the charge pump 2223. For example, the master power circuit 222 includes the bandgap reference voltage generation circuit 2221, but the disclosure is not limited thereto. Therefore, the master power circuit 222 stops generating the master voltages VM1 and VM2 in response to the first value of the master control signal SC2.

In some embodiments, the master power circuit 222 may include two of the bandgap reference voltage generation circuit 2221, the voltage regulator 2222, and the charge pump 2223. For example, the master power circuit 222 includes the bandgap reference voltage generation circuit 2221 and the charge pump 2223, but the disclosure is not limited thereto. Therefore, the master power circuit 222 stops generating the master voltages VM1, VM2, VM5, and VM6 in response to the first value of the master control signal SC2.

In summary, the DRAM device includes at least one slave DRAM chip and the master DRAM chip. The slave power circuit of the slave DRAM chip stops generating at least one of the slave voltages in response to the first value of the slave control signal. Therefore, when the DRAM device only uses first category DRAM chip, the slave power circuit of the slave DRAM chip can be controlled to stop generating at least one of the slave voltages. In this way, when the DRAM device only uses first category DRAM chip, the power consumption of the DRAM device can be reduced.

Although the disclosure has been disclosed in the form of embodiments, they are not intended to limit the disclosure. Anyone with ordinary knowledge in the relevant technical field may make slight changes and modifications without departing from the spirit and scope of the disclosure. Therefore, the scope of protection of the disclosure shall be determined by the scope of the appended patent application.

What is claimed is:

1. A dynamic random-access memory (DRAM) device, comprising:
at least one slave DRAM chip, wherein each of the at least one slave DRAM chip comprises:
a slave control circuit, configured to generate a slave control signal according to a slave category signal and a setting signal; and
a slave power circuit, coupled to the slave control circuit and configured to stop generating at least one of a plurality of slave voltages in response to a first value of the slave control signal and generate the plurality of slave voltages in response to a second value of the slave control signal; and
a master DRAM chip, coupled to the at least one slave DRAM chip and configured to control an operation of the at least one slave DRAM chip, wherein the master DRAM chip comprises:
a master control circuit, configured to generate a master control signal according to a master category signal and the setting signal, and to control the master DRAM chip to generate a plurality of master voltages according to the master control signal,
wherein the slave category signal is different from the master category signal.

2. The DRAM device according to claim 1, wherein:
a logical value of the slave category signal is a first logical value, and
a logical value of the master category signal is a second logical value.

3. The DRAM device according to claim 2, wherein:
when the logical value of the setting signal is the first logical value, the logical value of the slave control signal is the first logical value, and
when the logical value of the setting signal is the second logical value, the logical value of the slave control signal is the second logical value.

4. The DRAM device according to claim 3, wherein:
the first logical value is a high logical value,
the second logical value is a low logical value, and
the slave control circuit performs a logical AND operation on the slave category signal and the setting signal to generate the slave control signal.

5. The DRAM device according to claim 1, further comprising:
a setting circuit, coupled to the slave control circuit and the master control circuit, and configured to generate the setting signal according to a setting operation of the DRAM device.

6. The DRAM device according to claim 5, wherein the setting circuit is implemented by a fuse circuit.

7. The DRAM device according to claim 5, wherein the setting circuit is disposed in one of the at least one slave DRAM chip.

8. The DRAM device according to claim 5, wherein the setting circuit is disposed in the master DRAM chip.

9. The DRAM device according to claim 1, wherein the slave power circuit comprises:
a bandgap reference voltage generation circuit, coupled to the slave control circuit and configured to stop generating at least one bandgap reference voltage of the plurality of slave voltages in response to a first value of the slave control signal and generate the at least one bandgap reference voltage of in response to a second value of the slave control signal.

10. The DRAM device according to claim 1, wherein the slave power circuit comprises:
a voltage regulator, coupled to the slave control circuit and configured to stop generating at least one power supply voltage of the plurality of slave voltages in response to a first value of the slave control signal and generate the at least one power supply voltage in response to a second value of the slave control signal.

11. The DRAM device according to claim 1, wherein the slave power circuit comprises:
a charge pump, coupled to the slave control circuit and configured to stop generating at least one pumping voltage of the plurality of slave voltages in response to a first value of the slave control signal and generate the at least one pumping voltage in response to a second value of the slave control signal.

12. The DRAM device according to claim 1, wherein the master DRAM chip further comprises:
a master power circuit, coupled to the master control circuit and configured to stop generating at least one of the plurality of master voltages in response to a first value of the master control signal and generate the plurality of master voltages in response to a second value the master control signal.

13. The DRAM device according to claim 1, wherein:
the at least one slave DRAM chip and the master DRAM chip are stacked on each other.
